(19) United States
(12) Patent Application Publication
(10) Pub. No.: US 2025/0015243 A1
(43) Pub. Date: Jan. 9, 2025

(54) DISPLAY DEVICE COMPRISING SEMICONDUCTOR LIGHT-EMITTING ELEMENT, AND MANUFACTURING METHOD THEREFOR

(71) Applicants: LG ELECTRONICS INC., Seoul (KR); LG DISPLAY CO., LTD., Seoul (KR)

(72) Inventors: Kyuhyun BANG, Seoul (KR); Jungmin KIM, Paju-si (KR); Gisang HONG, Paju-si (KR); Eunhye LEE, Paju-si (KR)

(73) Assignees: LG ELECTRONICS INC., Seoul (KR); LG DISPLAY CO., LTD., Seoul (KR)

(21) Appl. No.: 18/713,549

(22) PCT Filed: Jul. 8, 2022
(86) PCT No.: PCT/KR2022/009922

§ 371 Date: May 24, 2024

(30) Foreign Application Priority Data
Nov. 25, 2021 (KR) 10-2021-0164175

(51) Int. Cl. H01L 33/62

(52) U.S. Cl. CPC H01L 33/62; H01L 2933/0066

(57) ABSTRACT

A display device and a method of manufacturing the same according to an embodiment include a substrate, first assembly wiring and second assembly wiring alternately arranged on the substrate and overlapping each other, an insulating layer disposed between the first assembly wiring and the second assembly wiring, a planarization layer disposed on the first assembly wiring and the second assembly wiring, and having a first opening, and a light emitting device disposed inside the first opening, wherein the first electrode overlaps the first assembly wiring and the second assembly wiring. And, the first electrode is bonded to one of the first assembly wiring and the second assembly wiring.

### TECHNICAL FIELD

The embodiment relates to a display device and a manufacturing method thereof, and more specifically, to a display device using a semiconductor light emitting device and a manufacturing method thereof.

### BACKGROUND ART

Display devices used in computer monitors, TVs, mobile phones, etc. include Organic Light Emitting Display (OLED) devices that emit light on their own, and Liquid Crystal Display (LCD) devices that require a separate light source), micro-LED displays, etc.

Micro-LED display is a display that uses micro-LED, a semiconductor light emitting device with a diameter or cross-sectional area of 100 μm or less, as a display element.

Micro-LED displays use micro-LED, a semiconductor light emitting device, as a display device, so they have excellent performance in many characteristics such as contrast ratio, response speed, color gamut, viewing angle, brightness, resolution, lifespan, luminous efficiency, and luminance.

In particular, the micro-LED display has the advantage of being able to freely adjust the size and resolution and implement a flexible display because the screen may be separated and combined in a modular manner.

However, because large micro-LED displays require more than millions of micro-LEDs, there is a technical problem that makes it difficult to quickly and accurately transfer micro-LEDs to the display panel. Meanwhile, methods for transferring a semiconductor light emitting device to a substrate include a pick and place process, a laser lift-off method, or a self-assembly method.

Among these, the self-assembly method is a method in which the semiconductor light emitting device finds its assembly position within the fluid on its own, and is an advantageous method for implementing a large-screen display device.

Meanwhile, when transferring a light emitting device in a fluid, a problem arises where the assembly wiring is corroded by the fluid. Corrosion of the assembly wiring may cause an electrical short circuit and cause assembly defects.

Additionally, during self-assembly, problems may arise where the assembly force varies depending on the spacing between assembly wirings. Therefore, there is a need for technology to maintain a constant spacing between assembly wirings.

### DISCLOSURE

### Technical Problem

The technical object of the embodiment is to provide a display device and a manufacturing method thereof that improve the assembly rate of light emitting devices.

In addition, the technical object of the embodiment is to provide a display device and a manufacturing method thereof that precisely control the separation distance between a plurality of assembly wirings.

In addition, the technical object of the embodiment is to provide a display device and a manufacturing method thereof that minimize corrosion of assembly wiring.

In addition, the technical object of the embodiment is to provide a display device and a manufacturing method thereof that solve the problem of low self-assembly rate due to non-uniformity of DEP force in the self-assembly method.

The objects of the embodiment are not limited to the tasks mentioned above and include what may be understood from the specification.

### Technical Solution

A display device including a semiconductor light emitting device according to an embodiment may include a substrate;

First assembly wiring and second assembly wiring alternately arranged on the substrate and overlapping each other: an insulating layer disposed between the first assembly wiring and the second assembly wiring, a planarization layer disposed on the first assembly wiring and the second assembly wiring and having a first opening; and a light emitting device disposed inside the first opening, wherein a first electrode overlaps the first assembly wiring and the second assembly wiring, and the first electrode may be bonded to one of the first assembly wiring and the second assembly wiring.

Additionally, in the embodiment, the second assembly wiring is on the first assembly wiring, each of the first assembly wirings includes a first part that does not overlap the second assembly wiring and a second part that overlaps the second assembly wiring, wherein the first part and the second part may include different materials.

Additionally, in an embodiment, the second part may be a semiconductor material, and the first part and the second assembly wiring may be a conductive material.

Additionally, in an embodiment, the second part may be an oxide.

In addition, in the embodiment, the first assembly wiring may include a first conductive layer disposed on the substrate, and a first clad layer in contact with the first conductive layer, the second assembly wiring may include a second conductive layer disposed on the insulating layer, and a second clad layer in contact with the second conductive layer, and the first electrode of the light emitting device may be in contact with the second clad layer.

In addition, in the embodiment, the first conductive layer and the second conductive layer overlap the planarization layer, and a portion of each of the first clad layer and the second clad layer may be disposed inside the first opening.

Additionally, in the embodiment, the second clad layer may cover a portion of the first clad layer on the first clad layer.

In addition, in the embodiment, the first clad layer is divided into a first region and a second region,

The second clad layer may cover at least a portion of the second area.

Additionally, in an embodiment, the first area of the first clad layer may not vertically overlap the second clad layer.

Additionally, in an embodiment, the second region of the first clad layer may not be conductive.

Additionally, the embodiment may further include a third clad layer disposed on the first clad layer and in contact with the first electrode of the light emitting device.

Additionally, in the embodiment, the third clad layer may be supplied with power of the same polarity as the first clad layer.

In addition, a method of manufacturing a display device including a semiconductor light emitting device according to an embodiment may include forming a first assembly wiring on a substrate: forming an insulating layer on the first assembly wiring: forming a second assembly wiring on the insulating layer to be parallel to and partially overlap the first assembly wiring: making a portion of the first assembly wiring into a conductor: forming a planarization layer on the first assembly wiring and the second assembly wiring to expose a portion of the first assembly wiring and the second assembly wiring; and bonding the light emitting device to be in contact with the second assembly wiring.

Additionally, in the embodiment, forming the first assembly wiring on the substrate may include forming a semiconductor layer on the substrate.

In addition, in the embodiment, making a part of the first assembly wiring into a conductor may include doping the first assembly wiring on top of the first assembly wiring using the second assembly wiring as a mask.

In addition, in the embodiment, making a part of the first assembly wiring into a conductor may include applying a conductive material on the insulating layer: forming a photosensitive resin on the conductive material to overlap a portion of the first assembly wiring; etching the conductive material; and removing the photosensitive resin.

Additionally, in the embodiment, etching the conductive material may be a step of dry etching the conductive material.

Additionally, in the embodiment, the undoped region of the first assembly wiring may be completely covered by the second assembly wiring.

Additionally, in the embodiment, etching the conductive material may be a step of wet etching the conductive material.

Additionally, in the embodiment, the doped region of the first assembly wiring and the second assembly wiring may be spaced apart from each other.

### Advantageous Effects

According to the embodiment, there is a technical effect in that the wiring for self-assembly of the light emitting device can also be used as a wiring for driving the light emitting device.

In addition, in the embodiment, the first assembly wiring and the second assembly wiring are arranged to overlap each other, there is a technical effect of eliminating the process margin caused by separating the first assembly wiring and the second assembly wiring from each other and precisely controlling the part of the assembly wiring that generates an electric field when assembling a light emitting device.

In addition, in the embodiment, through the process of forming the first assembly wiring with a semiconductor material and then making it a conductor, by precisely adjusting the separation distance between the first assembly wiring and the second assembly wiring, there is a technical effect of improving the assembly rate of the light emitting device.

In addition, the embodiment has the technical effect of preventing corrosion of the conductive layer by using a clad layer that is resistant to corrosion.

In addition, the embodiment has the technical effect of improving the assembly rate by resolving the non-uniformity of DEP force in the self-assembly method.

For example, there is a technical effect of forming a DEP force uniformly by disposing an additional clad layer on the first assembly wiring.

The effects according to the embodiment are not limited to the contents exemplified above, and more diverse effects are included in the specification.

### DESCRIPTION OF DRAWINGS

FIG. 1 is a schematic plan view of a display device according to an embodiment.

FIG. 2 is a schematic enlarged plan view of a display device according to an embodiment.

FIG. 3 is a cross-sectional view of a display device according to an embodiment.

FIGS. 4A to 4C are process diagrams for explaining a manufacturing method of a display device according to an embodiment.

FIG. 5 is a cross-sectional view of a display device according to a second embodiment.

FIGS. 6A to 6D are process charts for explaining the manufacturing method of the display device according to the third embodiment.

FIGS. 7A to 7D are process charts for explaining the manufacturing method of the display device according to the fourth embodiment.

FIGS. 8A to 8C are process charts for explaining the manufacturing method of the display device according to the fifth embodiment.

FIGS. 9A to 9F are process charts for explaining the manufacturing method of the display device according to the sixth embodiment.

FIG. 10 is a cross-sectional view of a display device according to the seventh embodiment.

FIG. 11 is a cross-sectional view of a display device according to the eighth embodiment.

### MODE FOR INVENTION

Hereinafter, embodiments disclosed in this specification will be described in detail with reference to the attached drawings. The suffixes ‘module’ and ‘part’ for components used in the following description are given or used interchangeably in consideration of ease of specification preparation, and do not have distinct meanings or roles in themselves. In addition, the attached drawings are intended to facilitate easy understanding of the embodiments disclosed in this specification, and the technical ideas disclosed in this specification are not limited by the attached drawings. Additionally, when an element such as a layer, region or substrate is referred to as being ‘on’ another component, this includes either directly on the other element or there may be other intermediate elements in between.

Display devices described in this specification may include digital TVs, mobile phones, smart phones, laptop computers, digital broadcasting terminals, personal digital assistants (PDAs), portable multimedia players (PMPs), navigation, slate PCs, tablet PCs, ultra-books, desktop computers, etc. However, the configuration according to the embodiment described in this specification may be applied to a device capable of displaying even if it is a new product type that is developed in the future.

Hereinafter, an embodiment will be described with reference to the drawings.

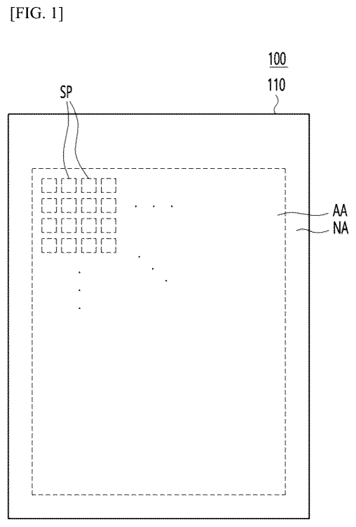

FIG. 1 is a schematic plan view of a display device according to an embodiment. For convenience of explanation, only the substrate 110 and the plurality of sub-pixels (SP) among the various components of the display device 100 are shown in FIG. 1.

The display device 100 according to the embodiment may include a flexible display manufactured on a thin and flexible substrate. Flexible displays may bend or curl like paper while maintaining the characteristics of existing flat displays.

In a flexible display, visual information may be implemented by independently controlling the light emission of unit pixels arranged in a matrix form. A unit pixel refers to the minimum unit for implementing one color. A unit pixel of a flexible display may be implemented by a light emitting device. In the embodiment, the light emitting device may be Micro-LED or Nano-LED, but is not limited thereto.

The substrate 110 is configured to support various components included in the display device 100, and may be made of an insulating material. For example, the substrate 110 may be made of glass or resin. Additionally, the substrate 110 may include polymer or plastic, or may be made of a material with flexibility.

The substrate 110 includes a display area (AA) and a non-display area (NA).

The display area (AA) is an area where a plurality of sub-pixels (SP) are arranged and an image is displayed. Each of the plurality of sub-pixels (SP) is an individual unit that emits light, and a light emitting device 130 and a driving circuit are formed in each of the plurality of sub-pixels (SP). For example, the plurality of sub-pixels SP may include, but are not limited to, a red sub-pixel, a green sub-pixel, a blue sub-pixel, and/or a white sub-pixel. Hereinafter, the description will be made on the assumption that the plurality of sub-pixels SP includes a red sub-pixel, a green sub-pixel, and a blue sub-pixel, but is not limited thereto.

The non-display area (NA) is an area where images are not displayed, and is an area where various wiring, driver ICs, etc. for driving the sub-pixels (SP) arranged in the display area (AA) are placed. For example, various ICs, such as gate driver ICs and data driver ICs, and driving circuits may be placed in the non-display area (NA). Meanwhile, the non-display area NA may be located on the back of the substrate 110, that is, on the side without the sub-pixel SP, or may be omitted, and is not limited to what is shown in the drawing.

The display device 100 of the embodiment may drive the light emitting device in an active matrix (AM, Active Matrix) method or a passive matrix (PM, passive matrix) method.

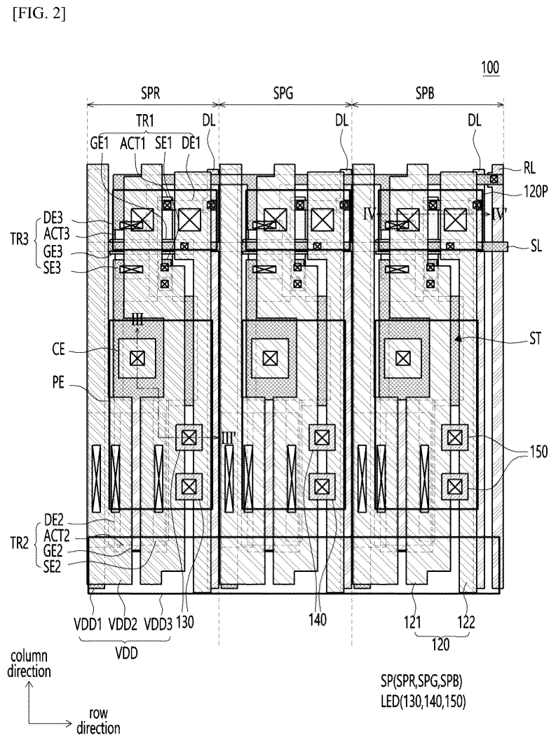

Hereinafter, FIGS. 2 and 3 will be referred to together for a more detailed description of the plurality of sub-pixels (SP).

FIG. 2 is a schematic enlarged plan view of a display device according to an embodiment. FIG. 3 is a cross-sectional view taken along line III-III′ of FIG. 2. Referring to FIGS. 2 and 3, the display device 100 according to an embodiment includes a plurality of scan wires (SL), a plurality of data wires (DL), a plurality of high potential power supply wires (VDD), a plurality of assembly wirings 120, and a plurality of reference wires (RL) and black matrix (BM) and a plurality of sub-pixels (SP), each of the first transistor (TR1), second transistor (TR2), third transistor (TR3), storage capacitor (ST), and semiconductor light emitting device (LED)), a light blocking layer (LS), a buffer layer 111, a gate insulating layer 112, a plurality of passivation layers 113, 115, 116, a plurality of planarization layers 114, 117, 118, a connecting electrode (CE), and Pixel electrode (PE), etc.

Referring to FIGS. 2 and 3, a plurality of data lines (DL), a first layer (VDD1) and a second layer (VDD2) of the high-potential power line (VDD), a plurality of reference lines (RL), and the plurality of assembly wirings 120 extend in the column direction between the plurality of sub-pixels SP, and the third layer VDD3 of the plurality of scan lines SL and the high potential power line VDD may extend in the row direction between the plurality of sub-pixels SP. Additionally, a first transistor TR1, a second transistor TR2, a third transistor TR3, and a storage capacitor ST may be disposed in each of the plurality of sub-pixels SP.

First, the first layer (VDD1) and the light blocking layer (LS) of the high-potential power supply line (VDD) may be disposed on the substrate 110.

The high-potential power supply line (VDD) is a line that transmits a high-potential power supply voltage to each of a plurality of sub-pixels (SP). A plurality of high-potential power supply lines (VDD) may transmit a high-potential power supply voltage to the second transistor TR2 of each of the plurality of sub-pixels (SP).

Meanwhile, a plurality of high-potential power supply lines (VDDs) may be made of a single layer or multiple layers, hereinafter, for convenience of explanation, the description will be made on the assumption that a plurality of high-potential power supply lines (VDDs) are composed of a plurality of layers.

The high-potential power line (VDD) includes a plurality of first layers (VDD1), a plurality of second layers (VDD2), and a plurality of third layers (VDD3) connecting them. The first layer VDD1 may extend in the column direction between each of the plurality of sub-pixels SP.

The light blocking layer LS may be disposed in each of the plurality of sub-pixels SP on the substrate 110. The light blocking layer LS blocks light incident from the lower part of the substrate 110 to the second active layer ACT2 of the second transistor TR2, which will be described later, and may prevent deterioration of the second transistor TR2.

The buffer layer 111 may be disposed on the first layer (VDD1) and the light blocking layer (LS) of the high-potential power line (VDD). The buffer layer 111 may reduce penetration of moisture or impurities through the substrate 110. The buffer layer 111 may be composed of, for example, a single layer or a multiple layer of silicon oxide (SiOx) or silicon nitride (SiNx), but is not limited thereto. However, the buffer layer 111 may be omitted depending on the type of substrate 110 or the type of transistor, but is not limited thereto.

A plurality of scan wires (SL), a plurality of reference wires (RL), a plurality of data wires (DL), a first transistor (TR1), a second transistor (TR2), a third transistor (TR3), and a storage capacitor (ST) may be disposed on the buffer layer 111.

First, the first transistor TR1 may be disposed in each of the plurality of sub-pixels SP. The first transistor TR1 may include a first active layer ACT1, a first gate electrode GE1, a first source electrode SE1, and a first drain electrode DE1. The first active layer (ACT1) may be disposed on the buffer layer (111). The first active layer ACT1 may be made of a semiconductor material such as oxide semiconductor, amorphous silicon, or polysilicon, but is not limited thereto.

The gate insulating layer 112 may be disposed on the first active layer ACT1. The gate insulating layer 112 is an insulating layer for insulating the first active layer (ACT1) and the first gate electrode (GE1), and may be composed of a single layer or multiple layers of silicon oxide (SiOx) or silicon nitride (SiNx). However, it is not limited to this.

The first gate electrode GE1 may be disposed on the gate insulating layer 112. The first gate electrode GE1 may be electrically connected to the scan line SL. The first gate electrode (GE1) may be made of a conductive material, for example, copper (Cu), aluminum (Al), molybdenum (Mo), nickel (Ni), titanium (Ti), chromium (Cr), or an alloy thereof, but is not limited to this.

The first passivation layer 113 may be disposed on the first gate electrode GE1. Contact holes are formed in the first passivation layer 113 to connect the first source electrode SE1 and the first drain electrode DE1 to the first active layer ACT1. The first passivation layer 113 is an insulating layer to protect the structure below the first passivation layer 113, and may be composed of a single layer or multiple layers of silicon oxide (SiOx) or silicon nitride (SiNx), but is limited thereto

A first source electrode (SE1) and a first drain electrode (DE1) electrically connected to the first active layer (ACT1) may be disposed on the first passivation layer 113. The first drain electrode DE1 may be connected to the data line DL, and the first source electrode SE1 may be connected to the second gate electrode GE2 of the second transistor TR2. The first source electrode (SE1) and the first drain electrode (DE1) are made of a conductive material, for example, copper (Cu), aluminum (Al), molybdenum (Mo), nickel (Ni), titanium (Ti), chromium (Cr) or an alloy thereof, but is not limited thereto.

Meanwhile, in the embodiment, each of the first source electrode (SE1) and the first drain electrode (DE1) was described as being connected to the second gate electrode (GE2) and the data line (DL), but depending on the type of transistor, the first source electrode SE1 may be connected to the data line DL, and the first drain electrode DE1 may be connected to the second gate electrode GE2 of the second transistor TR2, is not limited to this.

The first gate electrode GE1 of the first transistor TR1 is connected to the scan line SL and may be turned on or off depending on the scan signal. The first transistor TR1 may transmit a data voltage to the second gate electrode GE2 of the second transistor TR2 based on the scan signal, and may be referred to as a switching transistor.

Meanwhile, a plurality of data lines DL and a plurality of reference lines RL may be disposed on the gate insulating layer 112 along with the first gate electrode GE1. The plurality of data lines DL and the reference lines RL may be formed of the same material and process as the first gate electrode GE1.

The plurality of data lines DL are lines that transmit data voltages to each of the plurality of sub-pixels SP. The plurality of data lines DL may transmit data voltage to the first transistor TR1 of each of the plurality of sub-pixels SP. For example, the plurality of data lines (DL) may include a data line (DL) that transmits the data voltage to the red sub-pixel (SPR), a data line (DL) that transmits the data voltage to the green sub-pixel (SPG), and a data line (DL) that transmits data voltage to the blue sub-pixel (SPB).

The plurality of reference wires (RL) are wires that transmit a reference voltage to each of the plurality of sub-pixels (SP). The plurality of reference lines RL may transmit a reference voltage to the third transistor TR3 of each of the plurality of sub-pixels SP.

The second transistor TR2 may be disposed in each of the plurality of sub-pixels SP. The second transistor TR2 includes a second active layer ACT2, a second gate electrode GE2, a second source electrode SE2, and a second drain electrode DE2. The second active layer (ACT2) may be disposed on the buffer layer 111. The second active layer (ACT2) may be made of a semiconductor material such as oxide semiconductor, amorphous silicon, or polysilicon, but is not limited thereto.

The gate insulating layer 112 may be disposed on the second active layer ACT2, and the second gate electrode GE2 may be disposed on the gate insulating layer 112. The second gate electrode GE2 may be electrically connected to the first source electrode SE1 of the first transistor TR1. The second gate electrode GE2 may include a conductive material, such as copper (Cu), aluminum (Al), molybdenum (Mo), nickel (Ni), titanium (Ti), chromium (Cr), or an alloy thereof, but is not limited to this.

The first passivation layer 113 may be disposed on the second gate electrode (GE2), and the second source electrode (SE2) and the second drain electrode (DE2) may be disposed on the first passivation layer 113. The second source electrode SE2 is electrically connected to the second active layer ACT2. The second drain electrode DE2 is electrically connected to the second active layer ACT2 and at the same time is electrically connected to the high potential power supply line VDD. The second drain electrode DE2 may be disposed between the first layer VDD1 and the second layer VDD2 of the high potential power line VDD and electrically connected to the high potential power line VDD.

As the second gate electrode GE2 is connected to the first source electrode SE1 of the first transistor TR1, the second transistor TR2 may be turned on by the data voltage transmitted when the first transistor TR1 is turned on. And the turned-on second transistor TR2 may transfer a driving current to the light emitting device (LED) based on the high-potential power supply voltage from the high-potential power supply line (VDD), and thus may be referred to as a driving transistor.

The third transistor TR3 may be disposed in each of the plurality of sub-pixels SP. The third transistor TR3 may include a third active layer ACT3, a third gate electrode GE3, a third source electrode SE3, and a third drain electrode DE3. The third active layer (ACT3) may be disposed on the buffer layer 111. The third active layer (ACT3) may be made of a semiconductor material such as oxide semiconductor, amorphous silicon, or polysilicon, but is not limited thereto.

The gate insulating layer 112 may be disposed on the third active layer ACT3, and the third gate electrode GE3 may be disposed on the gate insulating layer 112. The third gate electrode GE3 is connected to the scan line SL, and the third transistor TR3 may be turned on or off by the scan signal. The third gate electrode GE3 may include a conductive material, such as copper (Cu), aluminum (Al), molybdenum (Mo), nickel (Ni), titanium (Ti), chromium (Cr), or an alloy thereof, but is not limited to this.

However, it was explained that the third gate electrode (GE3) and the first gate electrode (GE1) were connected to the same scan line (SL). The third gate electrode GE3 may be connected to a different scan line SL from the first gate electrode GE1, but is not limited thereto.

The first passivation layer 113 is disposed on the third gate electrode GE3, and the third source electrode SE3 and the third drain electrode DE3 are disposed on the first passivation layer 113. The third source electrode (SE3) is formed integrally with the second source electrode (SE2), may be electrically connected to the third active layer (ACT3), and may be electrically connected to the second source electrode (SE2) of the second transistor (TR2). And the third drain electrode DE3 may be electrically connected to the reference wiring RL.

The third transistor (TR3), which is electrically connected to the second source electrode (SE2), reference wiring (RL), and storage capacitor (ST) of the second transistor (TR2), which is a driving transistor, may be referred to as a sensing transistor.

A storage capacitor (ST) may be disposed in each of the plurality of sub-pixels (SP). The storage capacitor ST may include a first capacitor electrode ST1 and a second capacitor electrode ST2. The storage capacitor ST is connected between the second gate electrode GE2 and the second source electrode SE2 of the second transistor TR2, and may maintain the voltage level of the gate electrode of the second transistor TR2 constant while the light emitting device (LED) emits light.

The first capacitor electrode ST1 may be integrated with the second gate electrode GE2 of the second transistor TR2. Accordingly, the first capacitor electrode ST1 may be electrically connected to the second gate electrode GE2 of the second transistor TR2 and the first source electrode SE1 of the first transistor TR1.

The second capacitor electrode (ST2) may be disposed on the first capacitor electrode (ST1) with the first passivation layer 113 interposed therebetween. The second capacitor electrode ST2 may be integrated with the second source electrode SE2 of the second transistor TR2 and the third source electrode SE3 of the third transistor TR3. Accordingly, the second capacitor electrode ST2 may be electrically connected to the second transistor TR2 and the third transistor TR3.

Meanwhile, the first source electrode (SE1), the first drain electrode (DE1), the second source electrode (SE2), the second drain electrode (DE2), the third source electrode (SE3), and the third drain electrode (DE3) and a plurality of scan lines SL along with the second capacitor electrode ST2 may be disposed on the first passivation layer 113.

The plurality of scan wires (SL) are wires that transmit scan signals to each of the plurality of sub-pixels (SP). The plurality of scan lines SL may transmit scan signals to the first transistor TR1 of each of the plurality of sub-pixels SP. For example, each of the plurality of scan lines SL extends in the row direction and may transmit a scan signal to a plurality of sub-pixels SP arranged in the same row.

Next, the first planarization layer 114 may be disposed on a plurality of scan wires (SL), a plurality of reference wires (RL), a plurality of data wires (DL), a first transistor (TR1), a second transistor (TR2), a third transistor (TR3), and a storage capacitor (ST). The first planarization layer 114 may planarize the upper part of the substrate 110 on which the plurality of transistors are disposed. The first planarization layer 114 may be composed of a single layer or a double layer, and may be made of, for example, an acryl-based organic material, but is not limited thereto.

The second passivation layer 115 may be disposed on the first planarization layer 114. The second passivation layer 115 is an insulating layer for protecting the structure below the second passivation layer 115 and improving the adhesion of the structure formed on the second passivation layer 115, and may be composed of a single layer or multiple layers of silicon oxide (SiOx) or silicon nitride (SiNx), but is not limited thereto.

The second layer (VDD2) of the high-potential power supply line (VDD), the plurality of first assembly wiring lines 121 among the plurality of assembly wiring lines 120, and the connection electrode (CE) may be disposed on the second passivation layer 115.

First, the plurality of assembly wirings 120 generate an electric field for aligning the plurality of light emitting devices (LEDs) when manufacturing the display device 100, and may be a wiring that supplies a low-potential power supply voltage to a plurality of light emitting devices (LEDs) when the display device 100 is driven. Accordingly, the assembly wiring 120 may be referred to as a low-potential power wiring.

The plurality of assembly lines 120 may be arranged in a column direction along the plurality of sub-pixels SP arranged on the same line. The plurality of assembly wirings 120 may be arranged to overlap the plurality of sub-pixels SP arranged in the same column. For example, one first assembly wiring 121 and a second assembly wiring 122 may be disposed in a red sub-pixel (SPR) arranged in the same row, one first assembly wiring 121 and one second assembly wiring 122 may be disposed in the green sub-pixel (SPG), one first assembly wiring 121 and one second assembly wiring 122 may be disposed in the blue sub-pixel SPB.

The plurality of assembly wiring lines 120 may include a plurality of first assembly wiring lines 121 and a plurality of second assembly wiring lines 122. When the display device 100 is driven, the same low-potential voltage may be applied to the plurality of first assembly wirings 121 and the plurality of second assembly wirings 122 in alternating current. The plurality of first assembly wirings 121 and the plurality of second assembly wirings 122 may be alternately arranged. Additionally, in each of the plurality of sub-pixels SP, one first assembly wiring 121 and one second assembly wiring 122 may be disposed adjacent to each other.

The plurality of first assembly wirings 121 and the plurality of second assembly wirings 122 may be include a conductive material, for example, copper (Cu) and chromium (Cr), but are limited thereto.

The plurality of first assembly wirings 121 include a first conductive layer 121a and a first clad layer 121b. The first conductive layer 121a may be disposed on the second passivation layer 115. The first clad layer 121b may be in contact with the first conductive layer 121a. For example, the first clad layer 121b may be disposed to cover the top and side surfaces of the first conductive layer 121a. And the first conductive layer 121a may have a thickness greater than that of the first clad layer 121b.

The first clad layer 121b is made of a material that is more resistant to corrosion than the first conductive layer 121a, and when manufacturing the display device 100, the first conductive layer 121a and the second conductive layer 121a of the first assembly wiring 121 are used. Short circuit defects caused by migration of the second conductive layer 122a of the assembly wiring 122 may be minimized. For example, the first clad layer 121b may be made of molybdenum (Mo), molybdenum titanium (MoTi), etc., but is not limited thereto.

The second layer (VDD2) of the high potential power line (VDD) may be disposed on the second passivation layer (115). The second layer (VDD2) extends in the column direction between each of the plurality of sub-pixels (SP) and may overlap the first layer (VDD1). The first layer (VDD1) and the second layer (VDD2) may be electrically connected through a contact hole formed in the insulating layers formed between the first layer (VDD1) and the second layer (VDD2). The second layer VDD2 may be formed of the same material and process as the first assembly wiring 121, but is not limited thereto.

The connection electrode CE may be disposed in each of the plurality of sub-pixels SP. The connection electrode CE is electrically connected to the second capacitor electrode ST2 and the second source electrode SE2 of the second transistor TR2 through a contact hole formed in the second passivation layer 115. The connection electrode (CE) is an electrode for electrically connecting the light emitting device (LED) and the second transistor (TR2), which is a driving transistor, and may include a first connection layer (CE1) and a second connection layer (CE2). For example, the first connection layer CE1 may be formed of the same material on the same layer as the first conductive layer 121a of the first assembly wiring 121, and the second connection layer CE2 may be formed of the same material as the first clad layer 121b.

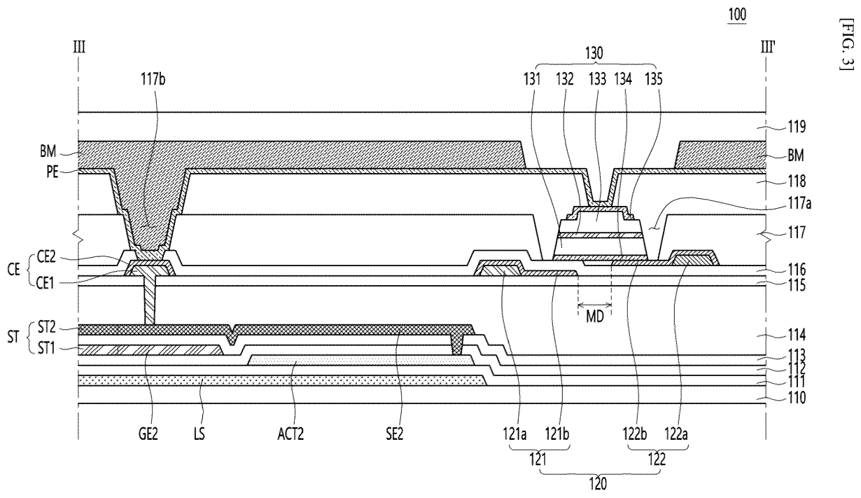

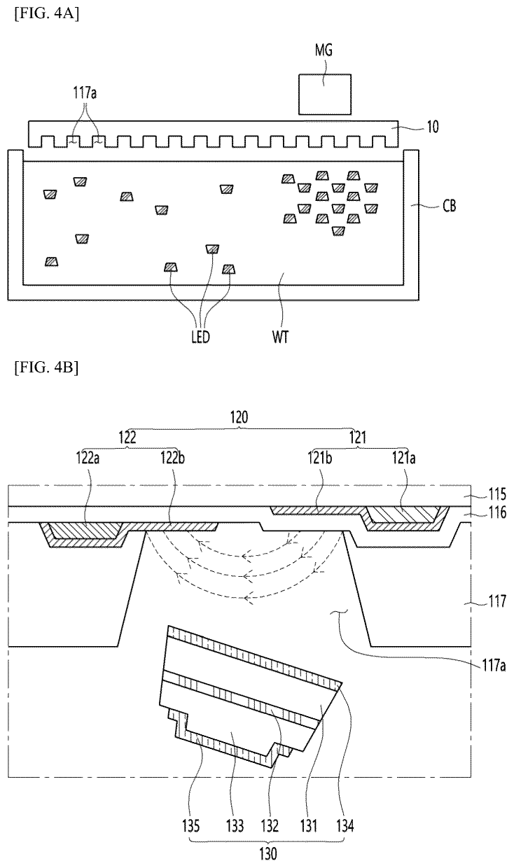

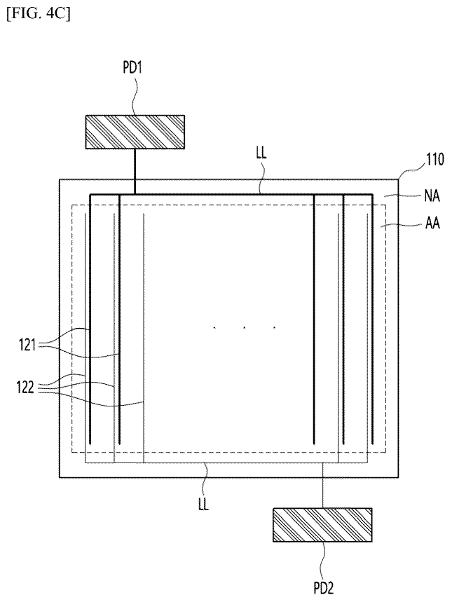

Next, the third passivation layer 116 may be disposed on the second layer (VDD2), the first assembly wiring 121, and the connection electrode (CE). The third passivation layer 116 is an insulating layer to protect the structure below the third passivation layer 116, and may be composed of a single layer or multiple layers of silicon oxide (SiOx) or silicon nitride (SiNx), but is not limited thereto. In addition, the third passivation layer 116 may function as an insulating layer to prevent short circuit defects due to migration between the first assembly wiring 121 and the second assembly wiring 122 when manufacturing the display device 100, this will be described later with reference to FIGS. 4A and 4B.

Among the plurality of assembly wiring lines 120, a plurality of second assembly wiring lines 122 may be disposed on the third passivation layer 116. Each of the plurality of second assembly wirings 122 is disposed in a plurality of sub-pixels (SP) arranged on the same line as described above, and the plurality of first assembly wirings 121 and the plurality of second assembly wirings 122 may be placed spaced apart from each other.

Each of the plurality of second assembly wirings 122 may include a second conductive layer 122a and a second clad layer 122b. The second conductive layer 122a may be disposed on the third passivation layer 116. And the second clad layer 122b may be electrically connected to the second conductive layer 122a. For example, the second clad layer 122b may be disposed to cover the top and side surfaces of the second conductive layer 122a. And the second conductive layer 122a may have a thickness greater than that of the second clad layer 122b.

The second clad layer 122b, like the first clad layer 121b, is also made of a material that is more resistant to corrosion than the second conductive layer 122a, so that when manufacturing the display device 100, short-circuit defects due to migration between the first assembly wiring 121 and the second assembly wiring 122 may be minimized. For example, the second clad layer 122b may be made of molybdenum (Mo), molybdenum titanium (MoTi), etc., but is not limited thereto.

As mentioned above, the second clad layer 122b and the first clad layer 121b are arranged to be spaced apart from each other without overlapping. However, if the distance between the first clad layer 122b and the second clad layer 121b is too far, the assembly rate of the light emitting device 130 decreases, the assembly rate of the light emitting device 130 may be improved by arranging the first clad layer 122b and the second clad layer 121b as close as possible. When the separation distance between the first clad layer 121b and the second clad layer 122b is MD, the separation distance MD inevitably includes a process margin, when the first clad layer 121b and the second clad layer 122b are formed as heterogeneous layers, there is a limit to precisely controlling the separation distance (MD) between the first clad layer 121b and the second clad layer 122b.

Next, the second planarization layer 117 may be disposed on the plurality of second assembly wirings 122. The second planarization layer 117 may be composed of a single layer or a double layer, and may be made of, for example, an acryl-based organic material, but is not limited thereto.

Meanwhile, the second planarization layer may include a plurality of first openings 117a on which each of the plurality of light emitting devices (LED) is seated, and a plurality of second openings 117b exposing each of the plurality of connection electrodes (CE).

A plurality of first openings 117a may be disposed in each of the plurality of sub-pixels SP. At this time, more than one first opening 117a may be disposed in one sub-pixel SP. For example, one first opening 117a or two first openings 117a may be disposed in one sub-pixel SP.

The plurality of first openings 117a are parts into which a plurality of light emitting devices (LEDs) are inserted, and may also be referred to as pockets. The plurality of first openings 117a may be formed to overlap the plurality of assembly wirings 120. For example, one first opening 117a may overlap the first assembly wiring 121 and the second assembly wiring 122 arranged adjacent to each other in one sub-pixel SP.

Additionally, a portion of the second clad layer 122b of the plurality of second assembly wirings 122 may be exposed through the first opening 117a. On the other hand, because the third passivation layer 116 covers all of the first assembly wiring 121 in the first opening 117a, the first assembly wiring 121 overlaps the first opening 117a, but may not be exposed from the first opening 117a.

Subsequently, a plurality of second openings 117b may be disposed in a plurality of sub-pixels SP. The plurality of second openings 117b are portions that expose the connection electrodes CE of each of the plurality of sub-pixels SP. The connection electrode (CE) under the second planarization layer 117 is exposed through the plurality of second openings 117b and may be electrically connected to the light emitting device (LED), and an transmit the driving current from the second transistor TR2 to the light emitting device (LED). In this case, the third passivation layer 116 may have a contact hole in the area overlapping the second opening 117b, and the connection electrode CE may be exposed from the second planarization layer 117 and the third passivation layer 116.

A plurality of light emitting devices (LEDs) may be disposed in the plurality of first openings 117a. The plurality of light emitting devices (LEDs) are light emitting devices (LEDs) that emit light by electric current. The plurality of light emitting devices (LEDs) may include light emitting devices (LEDs) that emit red light, green light, blue light, etc., and a combination of these may produce light of various colors, including white. For example, the light emitting device (LED) may be a light emitting diode (LED) or a micro LED, but is not limited thereto. In this case, micro LED may mean that the size of the light emitting device is 100 μm or less.

Hereinafter, the description will be made on the assumption that the plurality of light emitting devices (LEDs) include a red light emitting device 130 disposed in the red sub-pixel (SPR), a green light emitting device 140 disposed in the green sub-pixel (SPG), and a blue light emitting device 150 disposed in the blue sub-pixel (SPB). However, the plurality of light emitting devices (LEDs) are composed of light emitting devices (LEDs) that emit light of the same color, images of various colors may be displayed using a separate light conversion member that converts light from a plurality of light emitting devices (LEDs) into light of different colors, but is not limited thereto.

The plurality of light emitting devices (LEDs) may include a red light emitting device 130 disposed in a red sub-pixel (SPR), a green light emitting device 140 disposed in the green sub-pixel (SPG) and a blue light emitting device 150 disposed in the blue sub-pixel (SPB). Each of the red light emitting device 130, the green light emitting device 140, and the blue light emitting device 150 may include a first semiconductor layer, a second semiconductor layer, a first electrode, and a second electrode in common. And the red light emitting device 130 may include a light emitting layer that emits red light, the green light emitting device 140 may include a light emitting layer that emits green light, and the blue light emitting device 150 may include a light emitting layer that emits blue light.

Referring to FIG. 3, the first and second semiconductor layers 133 may be disposed on the semiconductor layer 131 in the red light emitting device 130 disposed in the red sub-pixel (SPR). The first semiconductor layer 131 and the second semiconductor layer 133 may be layers formed by doping n-type and p-type impurities into a specific material. For example, the first semiconductor layer 131 and the second semiconductor layer 133 may include an AlInGaP-based semiconductor layer, For example, the first semiconductor layer 131 and the second semiconductor layer 133 may be a layer doped with a p-type or n-type impurity in a material such as indium aluminum phosphide (InAlP) or gallium arsenide (GaAs). The p-type impurity may be magnesium (Mg), zinc (Zn), beryllium (Be), etc., and the n-type impurity may be silicon (Si), germanium (Ge), tin (Sn), etc., but are not limited thereto.

The light emitting layer 132 that emits red light may be disposed between the first semiconductor layer 131 and the second semiconductor layer 133. The light emitting layer 132 may emit light by receiving holes and electrons from the first semiconductor layer 131 and the second semiconductor layer 133. The light emitting layer 132 may have a single-layer or multi-quantum well (MQW) structure.

The light emitting layer 132 may convert injected electrical energy into light with a specific wavelength within the range of about 570 nm to about 630 nm. The change in specific wavelength is determined by the size of the band gap of the light emitting diode. The band gap size may be adjusted by changing the composition ratio of Al and Ga. For example, as the composition ratio of Al increases, the wavelength becomes shorter.

The first electrode 134 may be disposed on the lower surface of the first semiconductor layer 131, and the second electrode 135 may be disposed on the upper surface of the second semiconductor layer 133. The first electrode 134 is an electrode bonded to the second assembly wiring 122 exposed through the first opening 117a, the second electrode 135 is an electrode that electrically connects the second semiconductor layer 133 to a pixel electrode (PE), which will be described later. The first electrode 134 and the second electrode 135 may be formed of a conductive material.

In this case, in order to bond the first electrode 134 to the second assembly wiring 122, the first electrode 134 may be made of a eutectic metal. For example, the first electrode 134 may include tin (Sn), indium (In), zinc (Zn), lead (Pb), nickel (Ni), gold (Au), platinum (Pt), and copper (Cu), but is not limited to this.

And both the green light emitting device 140 and the blue light emitting device 150 may be formed with the same or similar structure as the red light emitting device 130. For example, the green light emitting device 140 includes a first electrode, a first semiconductor layer on the first electrode, a green light emitting layer on the first semiconductor layer, a second semiconductor layer on the green light emitting layer, and a second electrode on the second semiconductor layer. The blue light emitting device may also include a structure in which a first electrode, a first semiconductor layer, a blue light emitting layer, a second semiconductor layer, and a second electrode are sequentially stacked.

However, the green light emitting device 140 and the blue light emitting device 150 are formed of a compound selected from the group consisting of GaN, AlGaN, InGaN, AlInGaN, GaP, AlN, GaAs, AlGaAs, InP, and mixtures thereof, but it is not limited to this.

Meanwhile, although not shown in the drawing, an insulating layer surrounding a portion of each of the plurality of light emitting devices (LEDs) may be disposed. Specifically, the insulating layer may cover at least a side surface of the plurality of light emitting devices (LEDs) among the outer surfaces of the light emitting devices (LEDs). Protects the light emitting device (LED) by forming an insulating layer on the light emitting device (LED), when forming the first electrode 134 and the second electrode 135, electrical short circuit between the first semiconductor layer 131 and the second semiconductor layer 133 may be prevented.

Next, the third planarization layer 118 may be disposed on the plurality of light emitting devices (LEDs). The third planarization layer 118 may planarize the upper part of the substrate 110 on which a plurality of light emitting devices (LEDs) are disposed, and a plurality of light emitting devices (LEDs) may be stably fixed in the first opening 117a by the third planarization layer 118. The third planarization layer 118 may be composed of a single layer or a double layer, and may be made of, for example, an acryl-based organic material, but is not limited thereto.

The pixel electrode (PE) may be disposed on the third planarization layer 118. The pixel electrode (PE) is an electrode for electrically connecting a plurality of light emitting devices (LED) and the connection electrode (CE). The pixel electrode (PE) may be electrically connected to the light emitting device (LED) of the first opening (117a) and the connection electrode (CE) of the second opening (117b) through a contact hole formed in the third planarization layer (118). Accordingly, the second electrode 135 of the light emitting device (LED), the connection electrode (CE), and the second transistor (TR2) may be electrically connected through the pixel electrode (PE).

The third layer (VDD3) of the high-potential power supply line (VDD) is disposed on the third planarization layer 118. The third layer (VDD3) may electrically connect the first layer (VDD1) and the second layer (VDD2) arranged in different rows. For example, the third layer (VDD3) extends in the row direction between the plurality of sub-pixels (SP), and may electrically connect the plurality of second layers (VDD2) of the high potential power supply line (VDD) extending in the column direction to each other. In addition, as the plurality of high-potential power supply lines (VDD) are connected in a mesh form through the third layer (VDD3), there is a technical effect of reducing the voltage drop phenomenon.

A black matrix (BM) may be disposed on the third planarization layer 118. The black matrix BM may be disposed between the plurality of sub-pixels SP on the third planarization layer 118. The black matrix (BM) may prevent color mixing between the plurality of sub-pixels (SP). The black matrix (BM) may be made of an opaque material, for example, black resin, but is not limited thereto.

The protective layer 119 may be disposed on the pixel electrode (PE), the third planarization layer 118, and the black matrix (BM). The protective layer 119 is a layer to protect the structure below the protective layer 119, and may be composed of a single layer or multiple layers of translucent epoxy, silicon oxide (SiOx), or silicon nitride (SiNx), but is not limited thereto.

Meanwhile, in the first opening 117a, the plurality of first assembly wirings 121 are spaced apart from the plurality of light emitting devices (LED), and only the plurality of second assembly wirings 122 may contact the plurality of light emitting devices (LEDs). This is to prevent defects that occur when a plurality of light emitting devices (LEDs) come into contact with both the first assembly wiring 121 and the plurality of second assembly wiring 122 during the manufacturing process of the display device 100. The third passivation layer 116 may be formed on the plurality of first assembly wirings 121, and the plurality of light emitting devices (LEDs) may be contacted only to the plurality of second assembly wirings 122. Hereinafter, a method of manufacturing the display device 100 according to an embodiment of the present invention will be described in detail with reference to FIGS. 4A to 4C.

Meanwhile, the plurality of light emitting devices 130 may be self-assembled inside the first opening 117a by the plurality of assembly wirings 120. Hereinafter, the self-assembly process of the plurality of light emitting devices 130 will be described with reference to FIGS. 4A to 4C.

FIGS. 4A to 4C are process diagrams for explaining a method of manufacturing a display device according to an embodiment. FIGS. 4A to 4C are process diagrams for explaining a process of self-assembling a plurality of light emitting devices 130 into the first opening 117a.

Referring to FIG. 4A, the light emitting device 130 is introduced into the chamber CB filled with the fluid WT. The fluid WT may include water, etc., and the chamber CB filled with the fluid WT may have an open top.

Next, the mother substrate 10 may be placed on the chamber CB filled with the light emitting device 130. The mother substrate 10 is a substrate composed of a plurality of substrates 110 forming the display device 100, when self-assembling the plurality of light emitting devices 130, the mother substrate 10 on which the plurality of assembly wirings 120 and the second planarization layer 117 are formed may be used.

And the mother substrate 10 formed with the first assembly wiring 121, the second assembly wiring 122, and the second planarization layer 117 is placed on the chamber CB or inserted into the chamber CB. At this time, the mother substrate 10 may be positioned so that the opening 116a of the second planarization layer 117 and the fluid WT face each other.

Next, the magnet MG may be placed on the mother substrate 10. The light emitting devices 130 that sink or float on the bottom of the chamber CB may move toward the mother substrate 10 by the magnetic force of the magnet MG.

At this time, the light emitting device 130 may include a magnetic material to move by a magnetic field. For example, the light emitting device 130 may include a ferromagnetic material such as iron, cobalt, or nickel.

Next, referring to FIGS. 4B and 4C, the light emitting device 130 moved toward the second planarization layer 117 by the magnet MG may be self-assembled in the first opening 117a by the electric field formed by the first assembly wiring 121 and the second assembly wiring 122.

An alternating voltage may be applied to the plurality of first assembly wirings 121 and the plurality of second assembly wirings 122 to generate an electric field. The light emitting device 130 may be dielectrically polarized by this electric field to have polarity. And the dielectrically polarized light emitting device 130 may be moved or fixed in a specific direction by dielectrophoresis (DEP), that is, an electric field. Accordingly, the plurality of light emitting devices 130 may be fixed within the opening 116a of the second planarization layer 116 using dielectrophoresis.

At this time, the same voltage is applied to the plurality of first assembly wirings 121 and the plurality of second assembly wirings 122 when driving the display device 100, but different voltages are applied when manufacturing the display device 100. To this end, when manufacturing the display device 100, the plurality of first assembly wirings 121 and the plurality of second assembly wirings 122 may be connected to different assembly pads and different voltages may be applied.

In this regard, referring to FIG. 4C, when manufacturing the display device 100 and self-assembling the plurality of light emitting devices 130, the plurality of assembly wirings 120 may be connected to the assembly pad. Specifically, on the mother substrate 10, a plurality of substrates 110 forming the display device 100, a plurality of assembly pads, and a plurality of connection portions for the assembly wiring 120 are disposed.

The plurality of assembly pads are pads for applying voltage to the plurality of assembly wirings 120, and may be electrically connected to a plurality of assembly wirings 120 disposed on each of the plurality of substrates 110 forming the mother substrate 10. A plurality of assembly pads may be formed on the mother substrate 10 outside the substrate 110 of the display device 100, and may be separated from the substrate 110 of the display device 100 when the manufacturing process of the display device 100 is completed. For example, voltage is applied to the plurality of first assembly wirings 121 through the first assembly pad PD1, a voltage may be applied to the plurality of second assembly wirings 122 through the second assembly pad PD2 to form an electric field for aligning the plurality of light emitting devices 130.

At this time, the plurality of first assembly wirings 121 arranged on one substrate 110 are connected into one using the link wiring LL, and the plurality of second assembly wirings 122 are also connected into one, each of the plurality of first assembly wirings 121 and the plurality of second assembly wirings 122 may be easily connected to the assembly pad.

For example, the plurality of first assembly wirings 121 may be connected to one through the link wiring LL, and the plurality of second assembly wirings 122 may also be connected to one through the link wiring LL. In this case, each of the plurality of first assembly wirings 121 and the plurality of second assembly wirings 122 disposed on one substrate 110 is not individually connected to the assembly pad, by electrically connecting the link wire LL connecting each of the plurality of first assembly wirings 121 and the plurality of second assembly wirings 122 into one and the assembly pad, a voltage for self-assembly of the light emitting device 130 may be easily applied to the plurality of first assembly wirings 121 and the plurality of second assembly wirings 122.

Therefore, after placing the mother substrate 10 in the chamber (CB) into which the plurality of light emitting devices 130 are inserted, an electric field may be formed by applying an alternating voltage to a plurality of assembly wirings 120 through a plurality of assembly pads, and a plurality of light emitting devices 130 may be easily self-assembled into the first opening 117a of the second planarization layer 117.

Next, the mother substrate 10 may be flipped 180° while the light emitting device 130 is fixed within the opening 116a using the electric fields of the plurality of first assembly wirings 121 and the plurality of second assembly wirings 122. In the embodiment, the mother substrate 10 may be turned over while voltage is applied to the plurality of first assembly wirings 121 and the plurality of second assembly wirings 122 and a subsequent process may be performed.

After the self-assembly process of the plurality of light emitting devices 130 is completed, the mother substrate 10 may be cut along the scribing line and separated into a plurality of substrates 110. Thereafter, through the link wire LL connecting the plurality of first assembly wirings 121 into one and the link wire LL connecting the plurality of second assembly wirings 122 into one, the same voltage may be easily applied to the plurality of first assembly wirings 121 and the plurality of second assembly wirings 122. For example, when driving the display device 100, by connecting the link wire LL that connects each of the plurality of first assembly wirings 121 and the plurality of second assembly wirings 122 into one and the driving IC, voltage may be applied to the plurality of first assembly wirings 121 and the plurality of second assembly wirings 122.

In the display device 100 and its manufacturing method according to an embodiment of the present invention, at least some of the plurality of assembly wirings 120 for self-assembly of the plurality of light emitting devices 130 may be used as wiring for applying a low-potential power supply voltage to the plurality of light emitting devices 130. When manufacturing the display device 100, a plurality of light emitting devices 130 floating in the fluid WT may be moved adjacent to the mother substrate 10 using a magnetic field. Subsequently, different voltages may be applied to the plurality of first assembly wirings 121 and the plurality of second assembly wirings 122 to form an electric field, the plurality of light emitting devices 130 may be self-assembled within the plurality of first openings 117a by an electric field. At this time, a wiring for supplying a low-potential voltage is separately formed and electrically connected to the first semiconductor layer 134 of the plurality of self-assembled light emitting devices 130, when driving the display device 100, a plurality of assembly wirings 120 may be used as wiring for supplying low-potential voltage to a plurality of light emitting devices 130. Accordingly, in the display device 100 according to the embodiment, the plurality of assembly wirings 120 may be used not only for self-assembly of the plurality of light emitting devices 130 but also as wiring for driving the plurality of light emitting devices 130.

FIG. 5 is a cross-sectional view of a display device according to a second embodiment. The second embodiment of FIG. 5 may adopt the features of the first embodiment, and the description will focus on the modified form of the assembly wiring.

Referring to FIG. 5, a plurality of assembly wirings 520 generate an electric field to align a plurality of light emitting devices (LEDs) when manufacturing the display device 500, and are a wiring that supplies a low-potential power voltage to a plurality of light emitting devices (LEDs) when the display device 500 is driven. Accordingly, the assembly wiring 520 may be referred to as a low-potential power wiring. The plurality of assembly wirings 520 are arranged in a column direction along the plurality of sub-pixels SP arranged on the same line. The plurality of assembly wirings 520 may be arranged to overlap the plurality of sub-pixels SP arranged in the same column. For example, one first assembly wiring 521 and a second assembly wiring 522 are disposed in a red sub-pixel (SPR) arranged in the same column, one first assembly wiring 521 and a second assembly wiring 522 are disposed in the green sub-pixel (SPG), and one first assembly wiring 521 and one second assembly wiring 522 may be disposed in the blue sub-pixel (SPB).

The plurality of assembly wiring lines 520 includes a plurality of first assembly wiring lines 521 and a plurality of second assembly wiring lines 522. When the display device 500 is driven, the same low-potential voltage may be applied as alternating current to the plurality of first assembly wirings 521 and the plurality of second assembly wirings 522. The plurality of first assembly wirings 521 and the plurality of second assembly wirings 522 may be alternately arranged. And in each of the plurality of sub-pixels SP, one first assembly wiring 521 and one second assembly wiring 522 are disposed adjacent to each other.

The plurality of first assembly wirings 521 and the plurality of second assembly wirings 522 may be made of a conductive material, such as copper (Cu) and chromium (Cr), but is not limited to this.

The plurality of first assembly wirings 521 may include a first conductive layer 121a and first clad layers 521b and 521c. The first conductive layer 121a may be disposed on the second passivation layer 115. The first clad layers 521b and 521c are electrically connected to the first conductive layer 121a. For example, the first clad layers 521b and 521c may be arranged to cover the top and side surfaces of the first conductive layer 121a. Additionally, the first conductive layer 121a may have a thickness greater than that of the first clad layers 521b and 521c.

As mentioned above, if the first clad layers 521b and 521c and the second clad layer 522b overlap each other or the distance between them is too long, the assembly rate of the light emitting device 130 decreases. Accordingly, the assembly rate of the light emitting device 130 may be improved by arranging the first clad layers 521b and 521c and the second clad layer 522b as close as possible without overlapping. However, since the separation distance between the first clad layers 521b and 521c and the second clad layer 522b may only be determined by considering the process margin, there is a limit to precisely controlling the separation distance. Accordingly, in the display device 500 according to the second embodiment, by overlapping the first clad layers 521b, 521c and the second clad layer 522b and making only a portion of the first clad layers 521b, 521c conductive, there is a technical effect of precisely controlling the separation distance between the first clad layers 521b and 521c and the second clad layer 522b and improving the assembly rate of the light emitting device 130.

The first clad layers 521b and 521c overlap the first opening 117a and may overlap the second clad layer 522b by being arranged to occupy more than half of the area of the first opening 117a.

The first clad layers 521b and 521c include a first area 521b and a second area 521c. As the first region 521b is a conductive region that is directly in contact with and electrically connected to the first conductive layer 121a, it is made of a material that is more resistant to corrosion than the first conductive layer 121a, when manufacturing the display device 500, there is a technical effect of reducing short circuit defects caused by migration of the first conductive layer 121a of the first assembly wiring 521 and the second conductive layer 522a of the second assembly wiring 522. The second region 521c is a region overlapping with the second clad layer 522b disposed on the first clad layers 521b and 521c and is made of an oxide semiconductor. For example, the second region 521c may include IGZO (Indium Gallium Zinc Oxide), ITZO (Indium Tin Zinc Oxide), ITZO (Indium Tin Zinc Oxide), ZnO (Zinc Oxide), SnO2 (Stannum Oxide), etc., but is not limited thereto.

Among the first clad layers 521b and 521c, the region that serves as the first assembly wiring 521 is the first region 521b, the first area 521b and the second clad layer 522b do not overlap. The separation distance between the first area 521b and the second clad layer 522b may be adjusted to be zero or very small. The manufacturing method of the assembly wiring 520 will be described later.

Next, the third passivation layer 116 is disposed on the first assembly wiring 521. The third passivation layer 116 is an insulating layer to protect the structure below the third passivation layer 116, and may be composed of a single layer or multiple layers of silicon oxide (SiOx) or silicon nitride (SiNx), but is not limited to this. Additionally, the third passivation layer 116 may function as an insulating layer to prevent short circuit defects due to migration between the first assembly wiring 521 and the second assembly wiring 522 when manufacturing the display device 500.

Among the plurality of assembly wiring lines 520, a plurality of second assembly wiring lines 522 may be disposed on the third passivation layer 116. Each of the plurality of second assembly wirings 522 is disposed in a plurality of sub-pixels (SP) arranged on the same line as described above, and the plurality of first assembly wirings 521 and the plurality of second assembly wirings 522 may be arranged to overlap each other.

Each of the plurality of second assembly wirings 522 may include a second conductive layer 522a and a second clad layer 522b. The second conductive layer 522a may be disposed on the third passivation layer 116. And the second clad layer 522b is in contact with the second conductive layer 522a and is electrically connected. For example, the second clad layer 522b may be disposed to cover the top and side surfaces of the second conductive layer 522a. And the second conductive layer 522a may have a thickness greater than that of the second clad layer 522b.

The second clad layer 522b is arranged to overlap the first clad layer 521b. In this case, the second clad layer 522b may be arranged to overlap the first opening 117a and occupy half of the area of the first opening 117a.

As the second clad layer 522b is made of a material that is more resistant to corrosion than the second conductive layer 522a, when manufacturing the display device 500, short-circuit defects due to migration between the first assembly wiring 521 and the second assembly wiring 522 may be minimized. For example, the second clad layer 522b may be made of molybdenum (Mo), molybdenum titanium (MoTi), etc., but is not limited thereto.

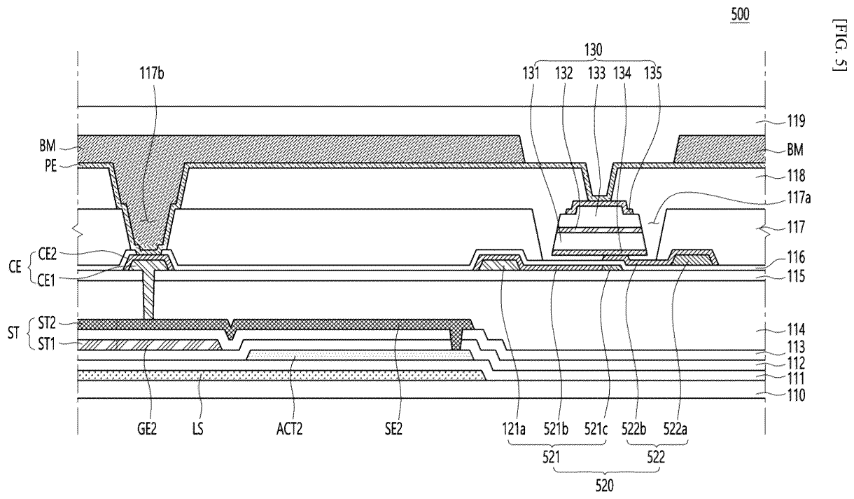

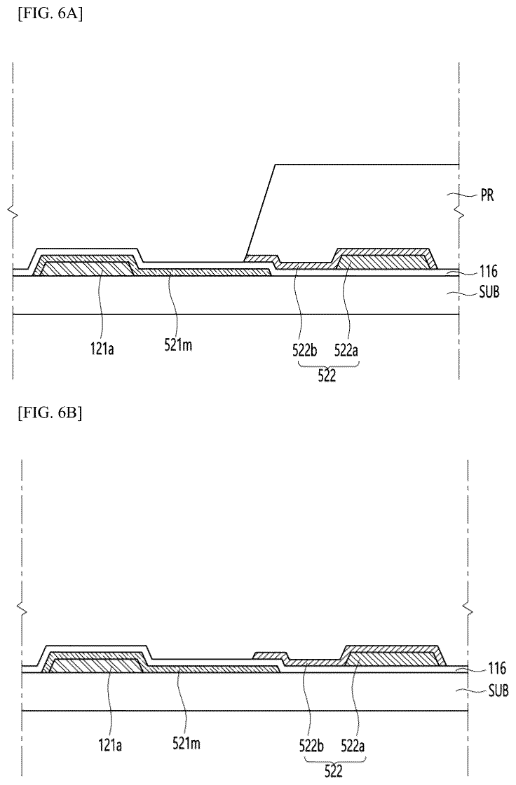

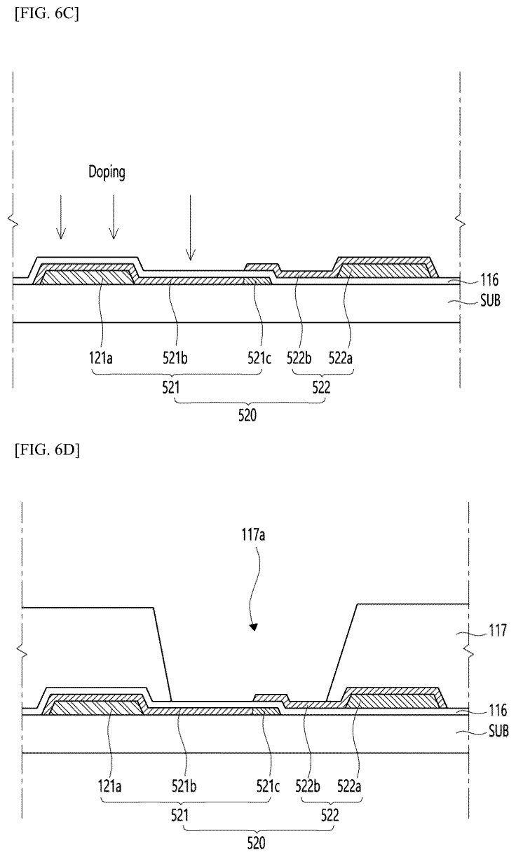

FIGS. 6A to 6D are process charts for explaining the manufacturing method of the display device according to the third embodiment. A method of manufacturing the assembly wiring 520 will be described based on the display device 500 of FIG. 5.

Referring to FIG. 6A, the second passivation layer 115 from the substrate 110 of FIG. 5 is briefly referred to as a TFT substrate (SUB). A first conductive layer 121a is formed on the TFT substrate (SUB). The first conductive layer 121a is formed of a conductive material through a deposition and patterning process. The deposition and patterning process may include deposition, photo resist coating, exposure, develop, etching, and photo resist strip.

Next, a first clad material layer 521m is deposited to cover the top and side surfaces of the first conductive layer 121a, and a patterning process is performed. The first clad material layer 521m may use an oxide semiconductor.

The third passivation layer 116 is formed on the patterned first clad material layer 521m. Then, a second conductive layer 522a is formed on the third passivation layer 116 through a deposition and patterning process to be spaced apart from the first conductive layer 121a and the first clad material layer 521m.

Next, a second clad layer 522b is formed through a deposition and patterning process to cover the top and side surfaces of the second conductive layer 522a. FIG. 6A shows the etching step of the second clad layer 522b before peeling off the photosensitive resin during the patterning process of the second clad layer 522b. A photosensitive resin (PR) is formed on the second clad layer (522b) so that the second clad layer (522b) overlaps a portion of the side and top surfaces of the first clad material layer (521m), and the portion of the second clad layer 522b that is not covered by the photosensitive resin (PR) is etched. In this case, the second clad layer 522b may be etched by dry etching.

FIG. 6b shows the photosensitive resin peeling process step, in which the photosensitive resin (PR) is removed.

Referring to FIG. 6C, FIG. 6C is a step of converting a portion of the first clad material layer 521m into a conductor. In this case, the second clad layer 522b functions as a mask, and conduction does not proceed in the area overlapping with the first clad material layer 521m. Conductivity is performed through a doping process that injects impurities into the first clad material layer (521m). For example, the impurity may be boron (B), phosphorus (In), nitrogen (N), etc. Among the first clad material layer 521m, the area in which conduction has progressed may be divided into a first area 521b, and the area in which conduction has not progressed may be divided into a second area 521c. Since the separation distance between the first region 521b of the first clad layers 521b and 521c and the second clad layer 522b is formed by the method of manufacturing the display device according to the third embodiment, there is no or very fine separation distance, there is a technical effect that the assembly rate of the light emitting device 130 can be improved.

Referring to FIG. 6D, FIG. 6D is a step of forming the second planarization layer 117 on the second clad layer 522b. The second planarization layer 117 is formed so that the first opening 117a is disposed at the location where the light emitting device 130 is to be disposed. By overlapping with a portion of the first clad layer (521b, 521c) and a portion of the second clad layer (522b), and adjusting the position of the first opening 117a so that the surface of the first area 521b and the second clad layer 522b facing each other is at the center of the first opening 117a, the first opening 117a may be formed. When assembling the light emitting device 130, as the portion actually used as the assembly wiring 520 is the first conductive layer 121a, the first region 521b, the second conductive layer 522a, and the second clad layer 522b, excluding the second region 521c, the electric field formed between the first assembly wiring 521 and the second assembly wiring 522 may be formed symmetrically and evenly at the center of the first opening 117a.

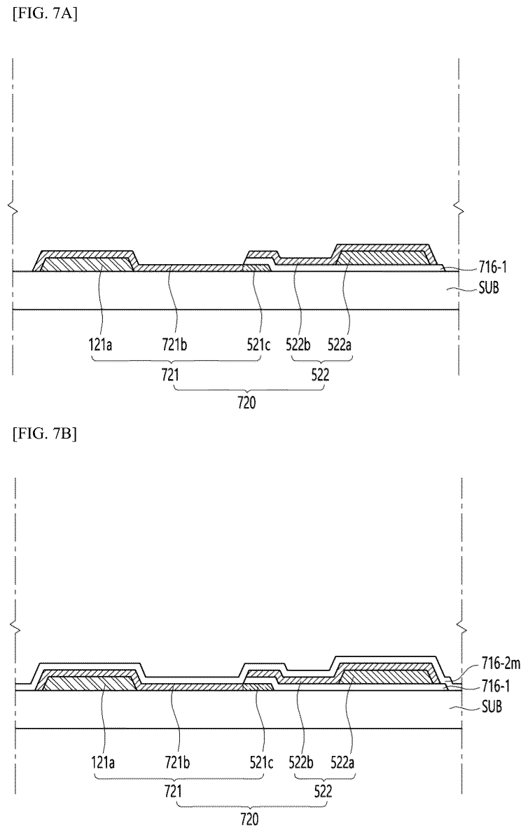

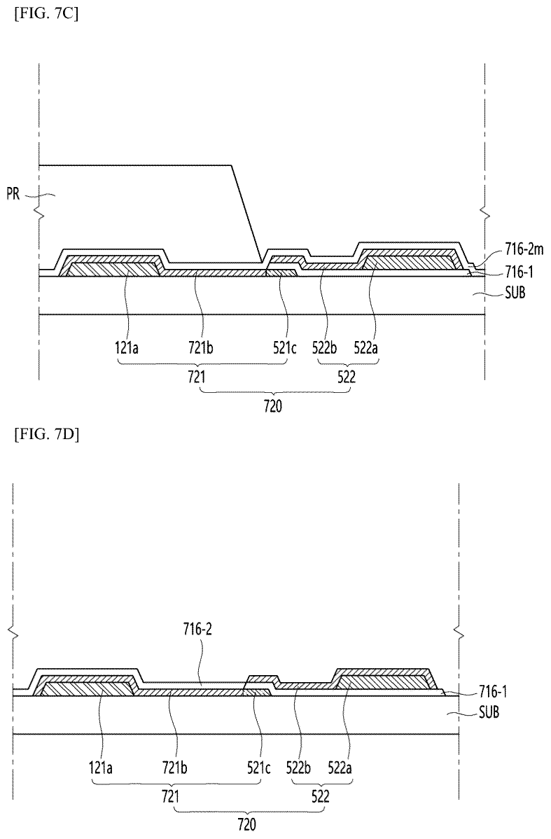

FIGS. 7A to 7D are process charts for explaining the manufacturing method of the display device according to the fourth embodiment. A method of manufacturing the assembly wiring 520 will be described based on the display device 500 of FIG. 5.

Referring to FIG. 7a, FIG. 7a is a step after the step of FIG. 6b, this is a step of removing the third passivation layer 116 on the first clad material layer 521m and converting a portion of the first clad material layer 521m into a conductor. 6A and 6B may be performed through the same process.

The first clad material layer 521m may use an oxide semiconductor. Referring to FIG. 6B, a third passivation layer 116 is disposed between the first clad material layer 521m and the second assembly wiring 522. After forming the second clad layer 522b, the third passivation layer 116 not covered by the second clad layer 522b is removed using an etching process. In this case, part of the third passivation layer 116 is removed through a dry etching process. For example, the gas used in the dry etching process may be a mixture of carbon tetrafluoride (CF4) and argon (Ar) or a mixture of carbon tetrafluoride (CF4) and helium (He). The removed third passivation layer 716-1 remains only under the second assembly wiring 522.

The gas used in the process of dry etching the third passivation layer 116 turns the first clad material layer 521m into a conductor. In this case, the second clad layer 522b functions as a mask and gas does not penetrate into the area overlapping the first clad material layer 521m, so conduction does not proceed. Among the first clad material layer 521m, the area in which conduction has progressed may be divided into a first area 721b, and the area in which conduction has not progressed may be divided into a second area 521c.

By the manufacturing method of the display device 500 according to the fourth embodiment, since the separation distance between the first region 721b and the second clad layer 522b of the first clad layers 721b and 521c is absent or formed very finely, there is a technical effect of improving the assembly rate of the light emitting device 130.

FIGS. 7B to 7D show that when the light emitting device 130 is assembled, it is electrically connected to the second assembly wiring 522 of the assembly wiring 720 and a process of forming an insulating layer on the first assembly wiring 721 to insulate it from the first assembly wiring 721.

FIG. 7b shows the step of forming the fourth passivation material layer 716-2m on the assembly wiring 720. FIG. 7C shows a step of patterning the photosensitive resin (PR) to cover the fourth passivation material layer 716-2m on the first region 721b. FIG. 7d shows the step of removing the fourth passivation material layer 716-2m on the second clad layer 522b. Accordingly, the fourth passivation layer 716-2 covering the first area 721b is formed.

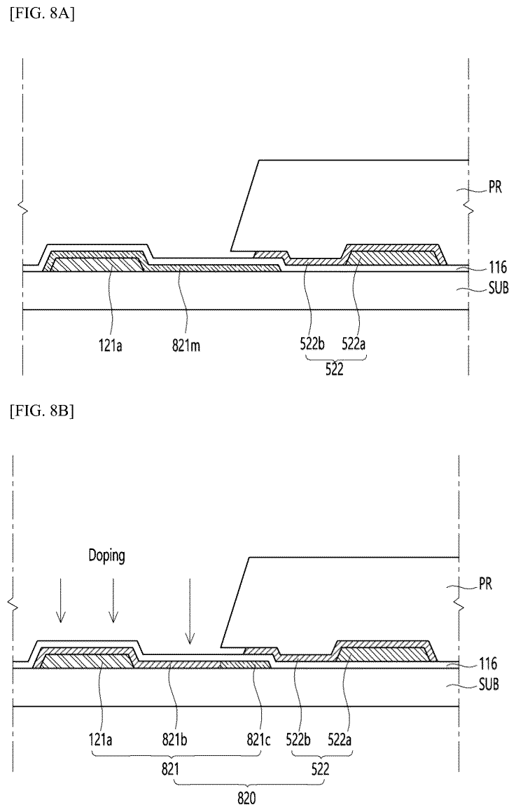

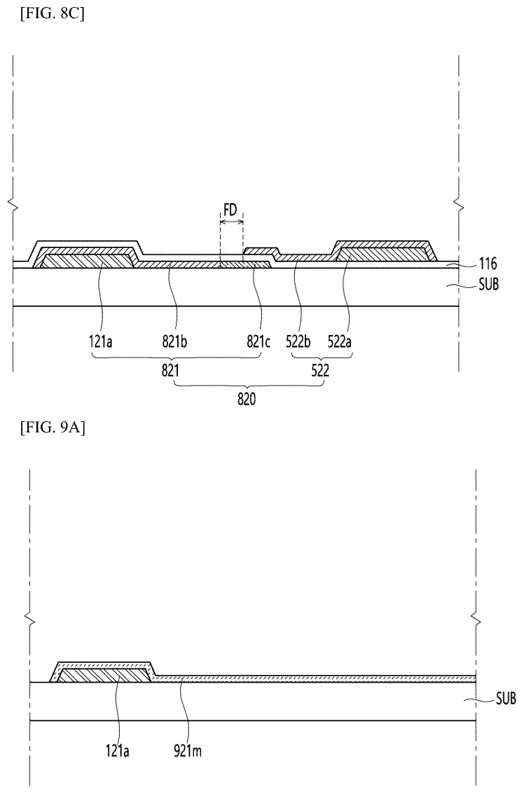

FIGS. 8A to 8C are process charts for explaining the manufacturing method of the display device according to the fifth embodiment. A method of manufacturing the assembly wiring 520 will be described based on the display device 500 of FIG. 5.

Referring to FIG. 8A, a first conductive layer 121a is formed on the TFT substrate (SUB), and a first clad material layer 821m is formed to cover the top and side surfaces of the first conductive layer 121a. The first clad material layer 821m may use an oxide semiconductor.

A third passivation layer 116 is formed on the patterned first clad material layer 521m, and a second clad layer 522b is formed on the third passivation layer 116 to cover the second conductive layer 522a and the top and side surfaces of the second conductive layer 522a.

FIG. 8a shows the etching step of the second clad layer 522b before peeling off the photosensitive resin during the patterning process of the second clad layer 522b. Specifically, the photosensitive resin (PR) is formed on the second clad layer 522b so that the second clad layer 522b overlaps a portion of the side and top surfaces of the first clad material layer 521m, the portion of the second clad layer 522b that is not covered with the photosensitive resin (PR) is etched. In this case, the second clad layer 522b may be etched by wet etching. By wet etching, the second clad layer 522b is etched to a portion of the inner region covered by the photosensitive resin (PR).

Referring to FIG. 8B, FIG. 8B is a step of converting a portion of the first clad material layer 821m into a conductor. In this case, the photosensitive resin (PR) functions as a mask, so the area overlapping with the photosensitive resin (PR) does not become conductive. Conductivity is performed through a doping process that injects impurities into the first clad material layer (821m). For example, the impurity may be boron (B), phosphorus (In), nitrogen (N), etc. Among the first clad material layer 821m, the area in which conduction has progressed may be divided into a first area 821b, and the area in which conduction has not progressed may be divided into a second area 821c.

FIG. 8c shows the photosensitive resin peeling process step, in which the photosensitive resin (PR) is removed. In this case, there is a separation distance FD between the first area 821b and the second clad layer 522b. The separation distance (FD) may be adjusted according to the degree of etching of the second clad layer 522b disposed below the photosensitive resin (PR), and fine and precise adjustment is possible. Separation distance (FD) is a more precise and smaller number than the previously mentioned separation distance MD.

Therefore, by the manufacturing method of the display device according to the fifth embodiment, since the separation distance between the first region 821b and the second clad layer 522b of the first clad layers 821b and 821c is absent or formed very finely, there is a technical effect of improving the assembly rate of the light emitting device 130.

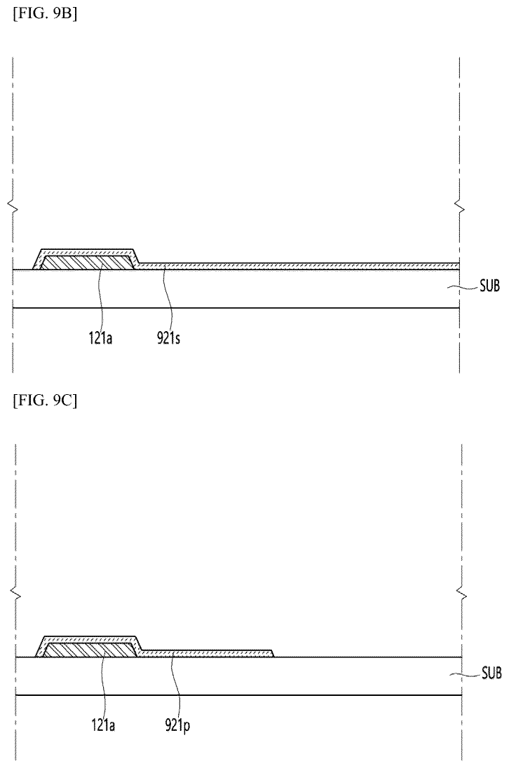

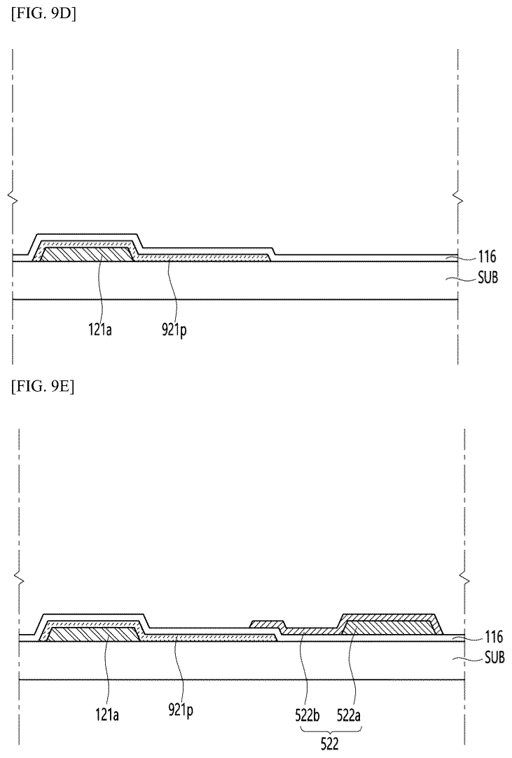

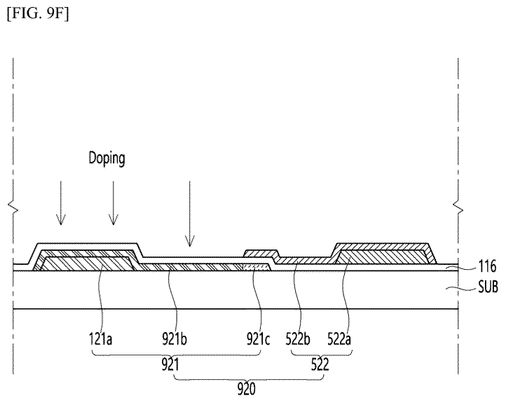

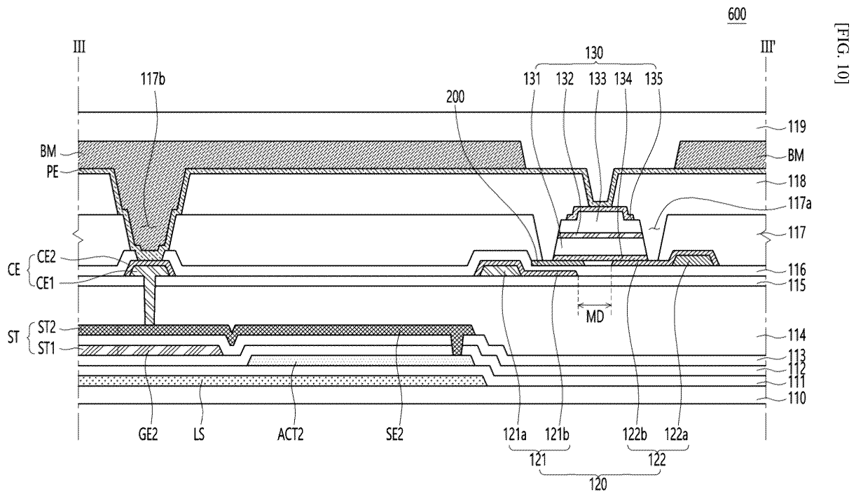

FIGS. 9A to 9F are process charts for explaining the manufacturing method of the display device according to the sixth embodiment. A method of manufacturing the assembly wiring 520 will be described based on the display device 500 of FIG. 5. Referring to FIG. 9A, FIG. 9A is a step of depositing the first clad material layer 921m. Specifically, a first conductive layer 121a is formed on the TFT substrate (SUB), and a first clad material layer 921m is deposited to cover the top and side surfaces of the first conductive layer 121a. In this case, the first clad material layer 921m may use silicon (Si).

Referring to FIG. 9B, FIG. 9B is a step of changing the physical properties to poly-silicon (Poly-Si) by dehydrogenating and crystallizing the first clad material layer (921m). The crystallized first clad material layer 921m will be referred to as the first clad material conversion layer 921s.

Referring to FIG. 9C, FIG. 9C is a step of patterning the first clad material conversion layer 921s. The patterned first clad material conversion layer 921s will be referred to as the first clad material patterning layer 921p. The first clad material patterning layer 921p is formed to cover a portion of the first conductive layer 121a and the TFT substrate SUB.

Referring to FIG. 9D, FIG. 9D is a step of forming the third passivation layer 116 on the first clad material patterning layer 921p.

Referring to FIG. 9e, FIG. 9e is a step of forming the second assembly wiring 522. Specifically, the second conductive layer 522a is formed on the third passivation layer 116 through a deposition and patterning process to be spaced apart from the first conductive layer 121a and the first clad material patterning layer 921p. Next, a second clad layer 522b is formed through a deposition and patterning process to cover the top and side surfaces of the second conductive layer 522a and overlap the first clad material patterning layer 921p.

Referring to FIG. 9F, FIG. 9F is a step of converting a portion of the first clad material patterning layer 921p into a conductor. In this case, the second clad layer 522b functions as a mask and the area overlapping the first clad material patterning layer 921p does not become conductive. Conductivity is performed through a doping process that injects impurities into the first clad material layer 921p. For example, the impurity may be boron (B), phosphorus (In), nitrogen (N), etc. Among the first clad material patterning layers 921p, the area where conductivity has progressed may be divided into a first area 921b, and the area where conductivity has not progressed may be divided into a second area 921c. Since the separation distance between the first region 921b of the first clad layers 921b and 921c and the second clad layer 522b is formed by the method of manufacturing the display device according to the sixth embodiment, there is no or very fine separation distance, there is a technical effect that the assembly rate of the light emitting device 130 can be improved.

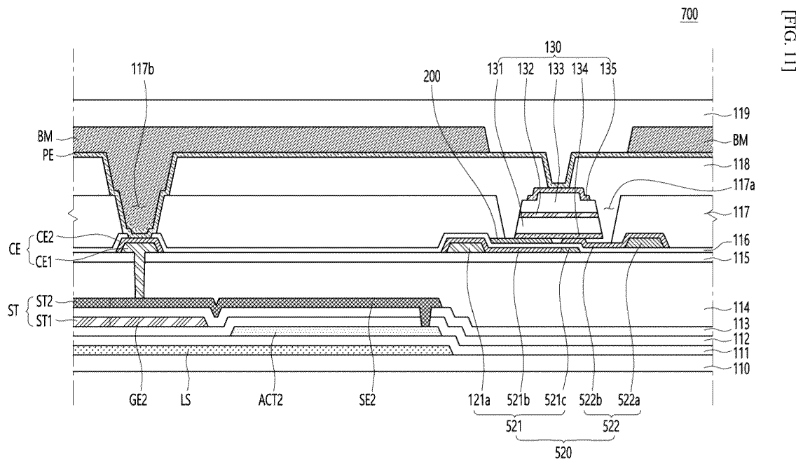

FIG. 10 is a cross-sectional view of a display device according to the seventh embodiment. FIG. 10 may adopt the features of the first embodiment of FIG. 3.

Meanwhile, the first clad layer 121b and the second clad layer 122b have a separation distance (MD), and there is a limit to precisely controlling the separation distance (MD), so the DEP force may be formed unevenly.

At this time, the floating clad layer 200 may be disposed on the first clad layer 121b. In detail, the third passivation layer 116 may be disposed on the first clad layer 121b, and the floating clad layer 200 may be disposed on the third passivation layer 116.

Additionally, the floating clad layer 200 is spaced apart from the second clad layer 200 and may be disposed to contact the first electrode 134 of the light emitting device 130. And, the floating clad layer 200 is supplied with power of the same polarity as the power applied to the first clad layer 121b. An alternating voltage is applied to the second clad layer 122b, the first clad layer 121b, and the floating clad layer 200, and an electric field may be formed. The light emitting device 130 may be fixed within the first opening 117a by the DEP force generated through this electric field.

Because the DEP force occurs not only between the first clad layer 121b and the second clad layer 122b, but also between the second clad layer 122b and the floating clad layer 200, even if the separation distance (MD) of the first clad layer 121b and the second clad layer 122b may not be precisely controlled, since the DEP force may be generated uniformly inside the first opening 117a, there is a technical effect in that the assembly rate of the light emitting device 130 can be improved.

In addition, because the floating clad layer 200 is located at the same height as the second clad layer 122b, there is a technical effect in that the DEP force just before assembly can be strengthened and the symmetry of the force acting on the LED chip may be secured after assembly.

In addition, the floating clad layer 200 may assemble a light emitting device by generating DEP force with the second assembly wiring 122 during self-assembly, after assembly, like the second assembly wiring 122, it may be used as a pixel electrode for driving the light emitting device by contacting the first electrode 134 of the light emitting device 130.

Therefore, the seventh embodiment has the complex technical effect of being able to generate a strong and uniform DEP force through the floating clad layer and using the assembly wiring as a pixel electrode that drives the light emitting device.

Next, FIG. 11 is a cross-sectional view of a display device according to the eighth embodiment. FIG. 11 may adopt the features of the second embodiment of FIG. 5. For example, in the 8th embodiment, the first clad layer 521b includes a first region 521b and a second region 521c, and the second region 521c may vertically overlap the second clad layer 522b. Through this, the separation distance between the first clad layers 521b and 521c and the second clad layer 522b may be precisely controlled and the assembly rate of the light emitting device 130 may be improved.

In the eighth embodiment, the floating clad layer 200 may be disposed on the first clad layer 521b. In detail, the third passivation layer 116 may be disposed on the first clad layer 521b, and the floating clad layer 200 may be disposed on the third passivation layer 116. Additionally, the floating clad layer 200 may be disposed to be spaced apart from the second clad layer 522b and in contact with the first electrode of the light emitting device 130.

And, the floating clad layer 200 is induced with power of the same polarity as the power applied to the first clad layer 521b. An alternating voltage is applied to the second clad layer 522b, the first clad layer 521b, and the floating clad layer 200, and an electric field may be formed. The light emitting device 130 may be fixed within the first opening 117a by the DEP force generated through this electric field.

Because the DEP force occurs not only between the first clad layer 521b and the second clad layer 522b, but also between the second clad layer 522b and the floating clad layer 200, there is a technical effect in that the DEP force can be generated uniformly and more strongly inside the first opening 117a, thereby improving the assembly rate of the light emitting device 130.

In addition, because the floating clad layer 200 is located at the same height as the second clad layer 122b, there is a complex technical effect in that the DEP force just before assembly can be strengthened and the symmetry of the force acting on the LED chip may be secured after assembly.

In addition, the floating clad layer 200 may assemble a light emitting device by generating DEP force with the second assembly wiring 122 during self-assembly, after assembly, the floating clad layer 200 may be used as a pixel electrode to drive the light emitting device by contacting the first electrode 134 of the light emitting device 130, like the second assembly wiring 122.

Therefore, the eighth embodiment has the complex technical effect of being able to generate a strong and uniform DEP force through the floating clad layer and using the assembly wiring as a pixel electrode that drives the light emitting device.

The display device including the semiconductor light emitting device and the manufacturing method thereof according to the above-described embodiment have the technical effect of being able to utilize the wiring for self-assembly of the light emitting device as the wiring for driving the light emitting device.

In addition, the embodiment arranges the first assembly wiring and the second assembly wiring to overlap each other, there is a technical effect of eliminating the process margin caused by separating the first assembly wiring and the second assembly wiring from each other and precisely controlling the part of the assembly wiring that generates an electric field when assembling a light emitting device.

In addition, as the embodiment precisely adjusts the separation distance between the first assembly wiring and the second assembly wiring through the process of forming the first assembly wiring with a semiconductor material and then making it a conductor, there is a technical effect that can improve the assembly rate of light emitting devices.

In addition, the embodiment has the technical effect of preventing corrosion of the conductive layer by using a clad layer that is resistant to corrosion.

In addition, the embodiment has the technical effect of forming the DEP force uniformly by arranging additional wiring on the first assembly wiring.

The above detailed description should not be construed as restrictive in any respect and should be considered illustrative. The scope of the embodiments should be determined by reasonable interpretation of the appended claims, and all changes within the equivalent scope of the embodiments are included in the scope of the embodiments. [Explanation of cited reference]
100, 500, 600, 700: Display device 110: Substrate 111: Buffer layer 112: Gate insulating layer
113: first passivation layer 114: first planarization layer 115: second passivation layer
116, 716-1: third passivation layer 117: second planarization layer 117a: first opening
118: Third planarization layer 119: Protective layer 120, 520, 720, 820, 920: Assembly wiring
121, 521, 721, 821, 921: first assembly wiring 121a: first conductive layer
121b, 521b, 521c: first clad layer 122, 522: second assembly wiring
122a, 522a: second conductive layer 122b, 522b: second clad layer 130: light emitting device
131: first semiconductor layer 132: light emitting layer 133: second semiconductor layer 134: first electrode
135: second electrode 200: floating clad layer 521b, 721b, 821b, 921b: first region 521c, 721c, 821c, 921c: second region 716-2: fourth passivation layer

### INDUSTRIAL APPLICABILITY

The embodiment may be adopted in the field of displays that display images or information.

The embodiment may be adopted in the field of displays that display images or information using semiconductor light emitting devices.

The embodiment may be adopted in the field of displays that display images or information using micro- or nano-level semiconductor light emitting devices.

1. A display device including a semiconductor light emitting device comprising:
a substrate;
a first assembly wiring and a second assembly wiring alternately arranged on the substrate and overlapping each other;
an insulating layer disposed between the first assembly wiring and the second assembly wiring;
a planarization layer disposed on the first assembly wiring and the second assembly wiring and comprising a first opening, and
a light emitting device in which a first electrode is configured to overlap the first assembly wiring and the second assembly wiring and is disposed inside the first opening,
wherein the first electrode is bonded to one of the first assembly wiring and the second assembly wiring.

2. The display device including the semiconductor light emitting device according to claim 1, wherein the second assembly wiring is disposed on the first assembly wiring,
wherein each of the first assembly wirings comprise a first part not to overlap with the second assembly wiring and a second part to overlap with the second assembly wiring, and
wherein materials of the first part and the second part different are different each other.

3. The display device including the semiconductor light emitting device according to claim 2, wherein a material of the second part is semiconductor, and a material of the first part and the second assembly wiring is a conductive material.

4. The display device including the semiconductor light emitting device according to claim 3,
wherein the material of the second part is an oxide.

5. The display device including the semiconductor light emitting device according to claim 1, wherein the first assembly wiring comprises a first conductive layer disposed on the substrate;
and a first clad layer in contact with the first conductive layer,
wherein the second assembly wiring comprises a second conductive layer disposed on the insulating layer and a second clad layer in contact with the second conductive layer, and wherein the first electrode of the light emitting device is in contact with the second clad layer.

6. The display device including the semiconductor light emitting device according to claim 5, wherein the first conductive layer and the second conductive layer are configured to overlap the planarization layer, and
wherein a portion of each of the first clad layer and the second clad layer is disposed inside the first opening.

7. The display device including the semiconductor light emitting device according to claim 5, wherein the second clad layer is configured to cover a portion of the first clad layer on the first clad layer.

8. The display device including the semiconductor light emitting device according to claim 7, wherein the first clad layer is divided into a first region and a second region, wherein the second clad layer is configured to cover at least a portion of the second region.

9. The display device including the semiconductor light emitting device according to claim 8, wherein the first region of the first clad layer is not configured to vertically overlap with the second clad layer.

10. The display device including the semiconductor light emitting device according to claim 8, wherein the second region of the first clad layer is not configured to become conductive.

11. The display device including the semiconductor light emitting device according to claim 5, further comprising a third clad layer disposed on the first clad layer and in contact with the first electrode of the light emitting device.

12. The display device including the semiconductor light emitting device according to claim 11, wherein the third clad layer is supplied with power of a same polarity as the first clad layer.

13. A method of manufacturing a display device including a semiconductor light emitting device comprising:
forming a first assembly wiring on a substrate;
forming an insulating layer on the first assembly wiring;
forming a second assembly wiring on the insulating layer to be parallel to and partially overlap the first assembly wiring;
making a portion of the first assembly wiring into a conductor;
forming a planarization layer on the first assembly wiring and the second assembly wiring to expose the portion of the first assembly wiring and the second assembly wiring, and
bonding the light emitting device to be in contact with the second assembly wiring.

14. The method of manufacturing the display device including the semiconductor light emitting device according to claim 13, wherein the forming the first assembly wiring on the substrate comprises forming a semiconductor layer on the substrate.

15. The method of manufacturing the display device including the semiconductor light emitting device according to claim 13, wherein the making the portion of the first assembly wiring into the conductor comprises doping the first assembly wiring on top of the first assembly wiring using the second assembly wiring as a mask.

16. The method of manufacturing the display device including the semiconductor light emitting device according to claim 15, wherein the making the portion of the first assembly wiring into the conductor comprises applying a conductive material on the insulating layer, forming a photosensitive resin on the conductive material to overlap the portion of the first assembly wiring, etching the conductive material, and removing the photosensitive resin

17. The method of manufacturing the display device including the semiconductor light emitting device according to claim 16, wherein the etching the conductive material is dry etching the conductive material.

18. The method of manufacturing the display device including the semiconductor light emitting device according to claim 17, wherein an undoped region of the first assembly wiring is completely covered by the second assembly wiring.

19. The method of manufacturing the display device including the semiconductor light emitting device according to claim 16, wherein the etching the conductive material is wet etching the conductive material.

20. The method of manufacturing the display device including the semiconductor light emitting device according to claim 19, wherein a doped region of the first assembly wiring and the second assembly wiring are spaced apart from each other.
